(19) United States
(12) Patent Application Publication
(10) Pub. No.: US 2016/0329892 A1
(43) Pub. Date: Nov. 10, 2016

(54) Electromagnetic Proximity Sensor and Method for Detecting a Target Object

(71) Applicant: SICK AG, Waldkirch (DE)

(72) Inventors: Sascha THOSS, Waldkirch (DE); Marc PASCHKE, Waldkirch (DE)

(21) Appl. No.: 15/141,944

(22) Filed: Apr. 29, 2016

(30) Foreign Application Priority Data
May 8, 2015 (DE) 10 2015 107 221.1

(51) Int. Cl. H03K 17/95; G01D 5/20

(52) U.S. Cl. CPC H03K 17/952; G01D 5/20

(57) ABSTRACT

An electromagnetic proximity sensor (10) for detecting a target object (20), the proximity sensor (10) comprising a sensor element (12) for generating a sensor signal that varies with a distance of the target object (20) and an evaluation unit (14) configured to detect a presence of the target object (20) in a switching distance (16) by comparing the sensor signal with a switching threshold (22), to detect at least one of an absence level (24a) of the sensor signal while no target object (12) affects the sensor signal and a presence level (24c) of the sensor signal while a target object (20) is detected as present, and to adapt the switching threshold (22) based on at least one of the absence level (24a) and the presence level (24c).

The invention relates to an electromagnetic proximity sensor and a method for detecting a target object according to the preamble of claims 1 and 10, respectively.

Proximity sensors detect the presence or approach of objects in a switching distance. The object in this context is often referred to as the target. Depending on the technology, objects with certain characteristics are detected. For example, an inductive proximity sensor detects conductive targets, in practice mainly metallic objects, while a capacitive proximity sensor is responsive to dielectric properties. Proximity sensors are often used as non-contact switches, with one switching state in the presence and the other switching state in the absence of a target in the switching distance.

Proximity sensors are often subject to a harsh environment with high temperature fluctuations, contamination, and wear by mechanical stress in particular of the object to be detected, which in addition increases aging of the sensor. These effects are collectively referred to as drift effects. Another problem are the so-called installation conditions. An inductive sensor is responsive to any metallic object in its proximity, not only to the object to be detected. A capacitive sensor is also influenced by the dielectric properties of the surroundings. Similar effects also exist in magnetic sensors or microwave sensors. Therefore, the switching distance may very strongly differ in a new environment or due to drift effects, which in practice means that the sensor used as a switch no longer switches on or off. The problem is more prominent for larger switching distances, because in that case the sensitivity of the sensors is increased.

Conventional proximity sensors have a fixed switching distance and do not provide additional information about the distance of the detected object. Among the drift effects, typically only temperature is considered, namely, in a classic temperature compensation by measuring temperature and using a correction table. An error remains, because the temperature of the measurement electronics is not the temperature of the actual sensor element, for example the sensor coil of an inductive sensor. The other effects mentioned above are not compensated at all.

For optical sensors, it is known from DE 10 2011 050 119 A1 to determine at least the first two moments of the distribution from a time series of the reception signal, to classify a state based thereon and then to derive a switching signal. Solutions for optical sensors cannot simply be adopted for the proximity sensors under consideration. The light signal of the optical sensor does not have similar distance dependence, and those sensors therefore do not have a switching distance. This does not imply that an optical sensor could not measure a distance and switch for certain distances, but an optical distance measurement is totally different, for example a triangulation or a light time of flight measurement, and is not related to the intensity of the sensor signal.

It is therefore an object of the invention to increase the robustness of the switching characteristics of an electromagnetic proximity sensor.

This object is satisfied by an electromagnetic proximity sensor, in particular an inductive sensor, for detecting a target object, the proximity sensor comprising a sensor element for generating a sensor signal that varies with a distance of the target object and an evaluation unit configured to detect a presence of the target object in a switching distance by comparing the sensor signal with a switching threshold, to detect at least one of an absence level of the sensor signal while no target object affects the sensor signal and a presence level of the sensor signal while a target object is detected as present, and to adapt the switching threshold based on at least one of the absence level and the presence level.

An electromagnetic proximity sensor generates a sensor signal depending on the distance of a target object with a sensor element and evaluates the sensor signal with a switching threshold to determine a presence of the target object in a switching distance. The invention starts from the basic idea to adapt the switching threshold to a level of the sensor signal which varies due to drift effects. To that end, a presence level while the target object is detected as present and an absence level while not target object affects the sensor signal, respectively, are measured. Under these conditions, variations in the presence or absence level are not caused by the distance of the target objects, but by the drift effects, and therefore the drift effects can be compensated by adapting the switching threshold. It should be noted that the presence and absence detected for the compensation is not necessarily identical with the two switching states. For example, an object in a distance a little larger than the switching distance does affect the sensor signal, i.e. it is still present in the sense of the drift compensation, but not in the sense of the switching state.

The object is also satisfied by a method for detecting a target object, wherein presence of the target object in a switching distance is detected from a sensor signal, which varies with a distance from the target object, by comparing the sensor signal with a switching threshold, wherein there is detected at least one of an absence level of the sensor signal while no target object affects the sensor signal and a presence level of the sensor signal while a target object is detected as present, and wherein the switching threshold is adapted based on at least one of the absence level and the presence level.

The invention has the advantage that unintentional shift of the switching distance and in particular a functional failure is prevented. The sensor therefore remains reliably operational even in harsh environments. Compensation of drift effects such as wear and aging of the sensor or its mounting, contamination or temperature fluctuations and an adaption to variations from the standard installation or changes in the installation environment is possible, in particular during operation.

The sensor element preferably comprises a transmission coil with an exciter circuit and a reception coil, wherein the sensor signal is derived from a voltage across the reception coil, or the sensor element comprises an oscillator circuit having a coil, wherein the sensor signal is derived from a voltage across the oscillator circuit. These are proven operating principles of an inductive proximity switch. The voltage in the reception coil and in the oscillator circuit, respectively, decreases due to eddy currents induced in a target object, and this effect increases with increasing proximity of the target object. Throughout this specification, preferably or preferred refers to a preferred, but completely optional feature.

The evaluation unit preferably is configured to adapt the switching threshold according to variations of the absence level. The switching threshold therefore is adjusted according to a drift of the absence level. Therefore, the switching distance remains constant despite drift effects. This approach is also called auto correction. Impacts of the drift effects on the switching distance of the sensor are eliminated, and thus the availability and robustness of the detection is considerably increased.

In an alternative preferred embodiment, the evaluation unit is configured to set a new switching threshold having a large noise margin with respect to the absence level and the presence level when adapting the switching threshold, in particular as their average. In this case, the goal is not to keep a constant switching distance, but the sensor redefines its switching threshold and thus its switching distance so that particularly robust switching properties are ensured which enable maximal noise immunity. This approach is also called auto detection. A sensor of that kind does not any more have a fixed switching distance, and therefore the switching distance does not need to be set. The sensor merely has a maximum possible detection range. Thus, the sensor model variance is considerably reduced, with corresponding cost advantages for the manufacturer and customer.

The evaluation unit preferably is configured to compare a temporal course of the sensor signal with a reference course during an expected movement of the target object and thus to determine points in time for the detection of at least one of the absence level and the presence level. In an important class of applications, the approach movement of the target object is cyclically repeated. Also in other cases, typical approach scenarios can be known and taught. By comparison with such a reference course, the sensor detects which variations of the sensor signal are due to the movement of the target object. The sensor therefore is able to determine points in time when the target object is present or absent in order to determine the respective levels for the threshold adaption.

The evaluation unit preferably is configured to determine points in time for the detection of at least one of the absence level and the presence level based on an analysis of the derivation of the sensor signal. Drift effects have an impact on the derivation of the sensor signal significantly differing from that of the movement of the target object. Drift effects generally are slower and have a same direction, such as for wear, aging, or contamination, or they are one-time effects such as for modifications. Therefore, analyzing the derivation provides a definition of points in time for determining the absence or presence levels, and in particular prevents to determine these levels during a movement of the target object, which would mistakenly adapt the threshold according to a largely random position of the target object rather than according to drift effects.

The evaluation unit is preferably configured to analyze the sensor signal for an expected temporal sequence of the sign of the derivation. In this case, no model for the quantitative course of the derivation needs to be set up and verified with tolerances which are difficult to determine, but merely a simple sequence of the sign of the derivation is monitored, which can be very robustly determined. One example for a sequence is a derivation which initially is negative, becomes positive directly or after a plateau at zero, and again falls to zero. This corresponds to a target cycle of a target object approaching and then moving away. As illustrated by the example, the value zero with a certain tolerance interval is understood to also be a sign of the derivation. Whether the derivation is positive or negative also depends on the sensor principle. Here, a sensor is assumed where the sensor signal decreases with increasing proximity of the target object, as in an inductive sensor. For other sensors having larger levels for nearby target objects, the signs are to be reversed accordingly.

The evaluation unit is preferably configured to detect conditions for a state transition in a state machine from the sign of the derivation of the sensor signal, wherein at least one of the absence level in a first state and a presence level in a further state is determined. A target cycle of approaching and subsequent moving away of a target object is modelled as a state machine or a classifier, respectively, wherein the sign of the derivation determines the conditions for a state transition or a change of class. Such a state machine is very easy to implement and enables a robust definition of states and thus points in time when the absence or presence levels required for the threshold adaption are determined.

The state machine preferably comprises a first state “waiting for target approach”, a second state “target approaches”, a third state “target is present” and a fourth state “target moves away”, with the following state transitions:
first state to second state when the derivation is negative;
second state to third state when the derivation is zero;
second state to fourth state when the derivation is positive;
third state to fourth state when the derivation is positive; and
fourth state to first state when the derivation is zero.
   This is a simple state machine which nevertheless describes the typical detection scenario of a proximity sensor, thus enabling a robust threshold adaption. The presence level can be measured in the third state. Alternatively, it is also conceivable to determine the presence level as a minimum in the transition from the second state to the fourth state. Then, in some embodiments, the third state and the related conditions for a state transition can even be dispensed with.

The inventive method can be modified in a similar manner and shows similar advantages. Further advantageous features are described in the sub claims following the independent claims in an exemplary, but non-limiting manner.

The invention will be explained in the following also with respect to further advantages and features with reference to exemplary embodiments and the enclosed drawing. The Figures of the drawing show in:

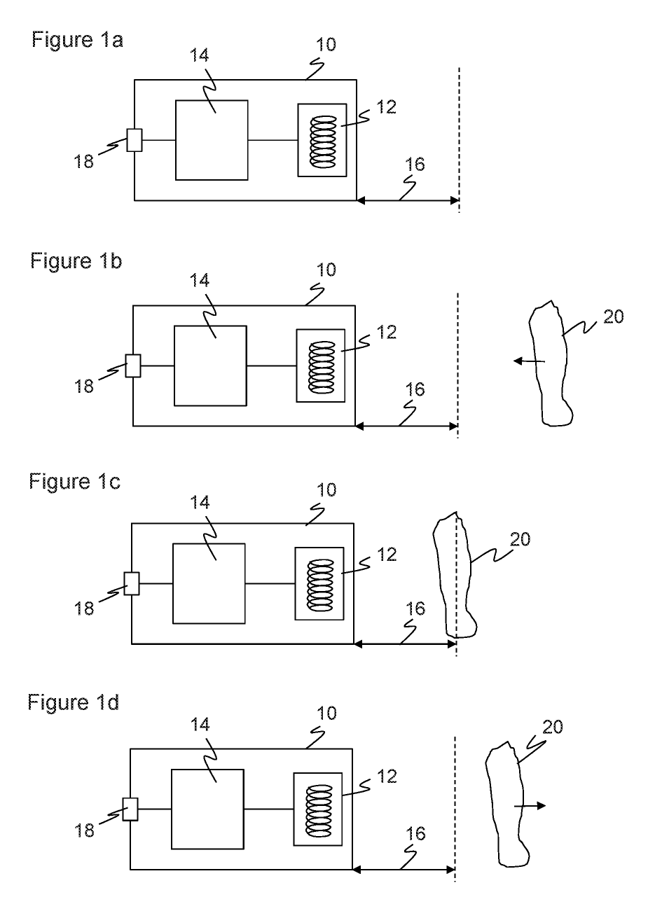

FIG. 1a-d a schematic representation of a proximity sensor over one target cycle of a target object approaching and moving away;

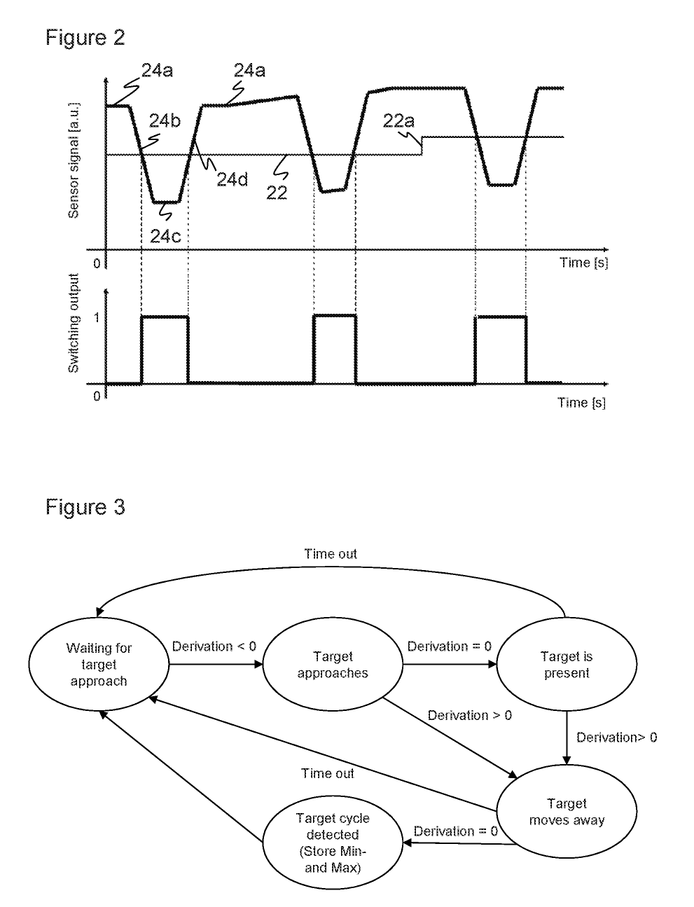

FIG. 2 exemplary temporal courses of a sensor signal and of a switching signal determined from that by means of a threshold; and

FIG. 3 an exemplary state diagram for the detection of a target cycle based on an analysis of the derivation.

FIG. 1 shows an inductive proximity sensor 10 in a very simplified schematic representation. The proximity sensor 10 comprises a sensor element 12 generating a sensor signal which is evaluated by an evaluation unit 14 with a switching threshold. This threshold corresponds to a defined switching distance 16 which in FIG. 1a is indicated by an arrow and a dotted line. A switching output generates an on or off signal depending on whether the sensor signal is above or below the threshold. A hysteresis can be implemented with two different thresholds for switching on and off.

The operating principle of an inductive proximity sensor 10 is known per se and is therefore not explained in detail. A usual principle is to provide a transmission coil and a reception coil in the sensor element 12. An exciter circle connected with the transmission coil generates an alternating field in the transmission coil which in turn induces a voltage in the reception coil. The evaluation unit 14 uses the voltage amplitude as the sensor signal. There are many alternatives to construct an inductive sensor with a different number and arrangement of coils. For example, another proven principle is to provide but one oscillator circuit with one coil, wherein the voltage across the oscillator circuit is the sensor signal.

FIGS. 1a-d show a typical so-called target cycle, where a target object 20 approaches the proximity sensor 10 and then moves away. FIG. 2 in its upper part illustrates an exemplary temporal course of the sensor signal during a plurality of target cycles and in its lower part shows a corresponding temporal course of the switching signal. The switching signal is generated by evaluation of the sensor signal with a threshold 22, which ultimately is a 1-bit quantization or binarization.

As long as no target object 20 is nearby as in FIG. 1a, the signal remains at a higher constant value as shown in FIG. 2, which in this specification is referred to as absence level 24a. Upon approach of the target object 20 as in FIG. 1b, eddy currents are induced in the conducting, often metallic target object 20 which lead to a decrease in the voltage across the reception coil or the oscillator circuit. Therefore, the sensor signal decreases the closer the target object 20 approaches the proximity sensor 10. Thus, in the sensor signal of FIG. 2, there is a falling edge 24b.

In FIG. 1c, the target object 20 has a distance of at most the switching distance 16 from the proximity sensor 10. While the target object 20 remains in that distance, another constant region forms in the sensor signal of FIG. 2 which in this specification is referred to as presence level 24c. When the target object subsequently moves away as in FIG. 1d, the sensor signal in FIG. 2 returns to the absence level 24a with a rising edge 24d, and after a certain interval, the next target cycle begins.

Movement of the target object 20 of course can also be transversal or have a transversal component, in contrast to what is shown. The explanation based on an inductive sensor 10 also is to be understood only as an example not limiting the invention. Sensor signals of other electromagnetic sensors, such as capacitive, magnetic or microwave sensors, show similar properties. However, it could be that the sensor signal is inverted, i.e. increases upon approaching the target object 20. The evaluation and the drift compensation according to the invention explained below can take this into account by a corresponding change of sign.

As explained in the introduction, there is a problem in the threshold evaluation resulting from the variations of the sensor signal by approaching the target object 20 being superimposed by interference or drift effects, which leads to shifts of switching distance 20 and in extreme cases to a loss of function. Therefore, the threshold 22 is adapted according to the invention.

However, it is possible to separate the influence of drift effects and movement of the target object 20 on the sensor signal. One solution is based on the drift effects being considerably slower, as in the case of wear, aging, contamination or temperature fluctuations, or being considerably less frequent than movements of the target objects, as in the case of a modified installation. The evaluation unit 14 can analyze the temporal variation of the sensor signal in order to determine when the target object 20 is absent and does not exert any influence on the sensor signal, and when it is present. One possible goal of this analysis is to detect the situations of FIGS. 1a and 1c, respectively, in order to determine the absence level 24a and/or the presence level 24c. This analysis requires consideration of the sensor signal which varies with the distance of the target object 20, and not only the switching signal. Moreover, one can use the fact that the drift effects affect the sensor signal almost identically irrespective of the position of the target object 20.

An absence or presence of the target object 20 may preferably be determined from an analysis of the derivation of the sensor signal. A target cycle, i.e. a pass of the target object 20 through the detection area of the proximity sensor 10 as illustrated in FIGS. 1a-d, generates a characteristic derivation pattern. The derivation patterns do not show any drift effects, but show only a very small derivation (temperature), always have a same sign (wear, aging) or appear only as a one-time event (change of installation).

As can be understood with reference to FIG. 2, the derivation which initially is constant, over a target cycle, becomes negative, followed by a plateau with derivation zero and a positive derivation which again drops to zero. The pattern of this sequence of the sign of the derivation can clearly be detected and distinguished from variations caused by interference or drift effects. After detection of a complete pass or target cycle, the evaluation unit 14 can assume that at this moment the target object 20 is absent and therefore the absence level 24a is available. In FIG. 2, the fast variations of the sensor signal due to movement of the target object 20 is superimposed with an exemplary slow upward drift, for example caused by a temperature variation. The derivation differs from zero also due to the drift, but with the detection of the sequence of the sign as described, this is reliably distinguished.

FIG. 3 illustrates one way to model the analysis of the derivation in a state machine and to thereby enable a simple evaluation. The states and conditions for state transitions can be understood from FIGS. 1 and 2. In the first state “waiting for target approach” there is no target object 20 in the vicinity of the proximity sensor 10 as in FIG. 1a, and the sensor signal corresponds to the absence level 24a. The transition to a second state “target approaches” as in FIG. 1b takes place when the derivation becomes negative in the falling edge 24b of the sensor signal. When subsequently the derivation again vanishes, the state machine transitions to a third state “target is present” corresponding to FIG. 1c. In this state, the presence level 24c can be measured. With a positive derivation in the rising edge 24d there is a transition to a fourth state “target moves away” corresponding to FIG. 1d. Alternatively, there is no measurable interval where the target object 20 is present after the second state, but it immediately moves away omitting the third state, and thus the second state directly transitions to the fourth state due to a positive derivation. In this case, the presence level 24c can be estimated as the minimum of the sensor signal.

With the derivation again vanishing in the fourth state, the target cycle has been completed, and the state machine returns to the first state. Prior to this, absence level 24a and/or presence level 24c can be stored as required. Returning to the first state can also occur by abortion due to a time out which is exemplarily shown in FIG. 3 for the third and fourth state.

The evaluation by a state machine or classifier is simple and robust. However, other evaluations are possible, for example by neural networks.

Knowledge of absence level 24a and/or presence level 24c enables an adaption of the threshold 22 to drift effects, as exemplarily shown in FIG. 2 at an adaption position 22a. Two preferred embodiments are explained in more detail below.

In an auto correct method, the proximity sensor 10 is to always switch in a same switching distance 16 in spite of the drift effects. To that end, the proximity sensor 10 is mounted for example at room temperature under certain installation conditions, and at this moment has a switching distance 16 which is acceptable for the user. The evaluation unit 14 initially and repeatedly determines the absence level 24a, for example cyclically at fixed time intervals or after each target cycle detected as complete. If this value has changed as compared to the value previously stored, the threshold 22 is modified by the difference of old value and new value. At least the value used for the latest threshold adaption or the initial value, respectively, is stored for later threshold adaptions. The threshold may, but does not need to be directly adapted by the respective difference of absence levels 24a, but a scaling factor or nonlinearities may also be taken into account.

With the auto correct method, the impact of drift effects on the switching threshold is almost eliminated, and the switching distance 16 constantly remains at the initial value for example set during installation.

In an alternative auto detection method, the proximity sensor 10 does not have a fixed switching distance, but always adapts the switching distance 16 so that the presence of a target object 20 is detected with the largest possible noise immunity. The threshold 22 is not only tracked, but redefined based on the absence level 24a and the presence level 24c. An exemplary robust threshold position is achieved by setting the threshold 22 at the average or midpoint between absence level 24a and presence level 24c.

In the auto detect method, the goal of the proximity sensor 10 is a detection as robust as possible, and the proximity sensor 10 in exchange gives up a fixed switching distance 16. In a manner of speaking, the proximity sensor 10 set is own switching distance. This has the advantage that effects of the installation are automatically eliminated immediately at startup, and that the material of the target object 20 is irrelevant for a reliable detection. Such proximity sensors 10 need only be designed for a maximum possible switching distance 16 and not a fixed switching distance 16. Any switching distance 16 smaller than the possible maximum is covered by one and the same device. This considerably reduces variance, logistics and procurement costs both for the manufacturer and the user of the proximity sensor 10.

1. An electromagnetic proximity sensor (10) for detecting a target object (20), the proximity sensor (10) comprising a sensor element (12) for generating a sensor signal that varies with a distance of the target object (20) and an evaluation unit (14) configured to detect a presence of the target object (20) in a switching distance (16) by comparing the sensor signal with a switching threshold (22), to detect at least one of an absence level (24a) of the sensor signal while no target object (12) affects the sensor signal and a presence level (24c) of the sensor signal while a target object (20) is detected as present, and to adapt the switching threshold (22) based on at least one of the absence level (24a) and the presence level (24c).

2. The proximity sensor (10) in accordance with claim 1,
wherein the proximity sensor (10) is an inductive sensor.

3. The proximity sensor (10) in accordance with claim 1,
wherein the sensor element (12) comprises a transmission coil with an exciter circuit and a reception coil, and wherein the sensor signal is derived from a voltage across the reception coil.

4. The proximity sensor (10) in accordance with claim 1,
wherein the sensor element (12) comprises an oscillator circuit having a coil, and wherein the sensor signal is derived from a voltage across the oscillator circuit.

5. The proximity sensor (10) in accordance with claim 1,
wherein the evaluation unit (14) is configured to adapt the switching threshold (22) according to variations of the absence level (24a).

6. The proximity sensor (10) in accordance with claim 1,
wherein the evaluation unit (14) is configured to set a new switching threshold (22) having a large noise margin with respect to the absence level (24a) and the presence level (24c) when adapting the switching threshold (22).

7. The proximity sensor (10) in accordance with claim 6,
wherein the new switching threshold (22) is set as the average of absence level (24a) and presence level (24c).

8. The proximity sensor (10) in accordance with claim 1,
wherein the evaluation unit (14) is configured to compare a temporal course of the sensor signal with a reference course during an expected movement of the target object (20) and thus to determine points in time for the detection of at least one of the absence level (24a) and the presence level (24c).

9. The proximity sensor (10) in accordance with claim 1,
wherein the evaluation unit (14) is configured to determine points in time for the detection of at least one of the absence level (24a) and the presence level (24c) based on an analysis of the derivation of the sensor signal.

10. The proximity sensor (10) in accordance with claim 9,
wherein the evaluation unit (14) is configured to analyze the sensor signal for an expected temporal sequence of the sign of the derivation.

11. The proximity sensor (10) in accordance with claim 9,
wherein the evaluation unit (14) is configured to detect conditions for a state transition in a state machine from the sign of the derivation of the sensor signal, wherein at least one of the absence level (24a) in a first state and a presence level (24c) in a further state is determined.

12. The proximity sensor (10) in accordance with claim 11,
wherein the state machine comprises a first state “waiting for target approach”, a second state “target approaches”, a third state “target is present” and a fourth state “target moves away”, with the following state transitions:
first state to second state when the derivation is negative;
second state to third state when the derivation is zero;
second state to fourth state when the derivation is positive;
third state to fourth state when the derivation is positive; and
fourth state to first state when the derivation is zero.

13. A method for detecting a target object (20), wherein presence of the target object (20) in a switching distance (16) is detected from a sensor signal, which varies with a distance from the target object (20), by comparing the sensor signal with a switching threshold (22), wherein there is detected at least one of an absence level (24a) of the sensor signal while no target object (20) affects the sensor signal and a presence level (24c) of the sensor signal while a target object (20) is detected as present, and wherein the switching threshold (22) is adapted based on at least one of the absence level (24a) and the presence level (24c).
